(19) United States
(12) Patent Application Publication
(10) Pub. No.: US 2026/0103822 A1
(43) Pub. Date: Apr. 16, 2026

(54) GROUP III-NITRIDE CRYSTAL PRODUCTION APPARATUS AND WAFER TRAY

(71) Applicant: Panasonic Holdings Corporation, Osaka (JP)

(72) Inventors: Junichi TAKINO, Osaka (JP); Masayuki HOTEIDA, Osaka (JP)

(21) Appl. No.: 19/356,677

(22) Filed: Oct. 13, 2025

(30) Foreign Application Priority Data
Oct. 15, 2024 (JP) 2024-179804

(51) Int. Cl. C30B 25/12; C30B 29/40

(52) U.S. Cl. CPC C30B 25/12; C30B 29/403

(57) ABSTRACT

A Group III nitride crystal production apparatus has a growth chamber in which a Group III element oxide gas reacts with a nitrogen-containing gas to grow a Group III nitride crystal on a seed substrate, wherein the growth chamber includes a wafer tray on which the seed substrate is disposed via a decomposition-suppressing sheet.

### CROSS REFERENCE TO RELATED APPLICATION

This application claims a priority of Japanese Patent Application No. 2024-179804 filed on October 15, 2024, the contents of which are incorporated herein by reference.

### BACKGROUND OF THE INVENTION

### 1. Field of the Invention

The present disclosure relates to a Group III nitride crystal production apparatus and a wafer tray for placing thereon a seed substrate used in the production apparatus.

### 2. Description of the Related Art

Group III nitride crystals such as GaN are expected to be applied to next-generation optical devices such as high-power light-emitting diodes (LEDs) and laser diodes (LDs), as well as next-generation electronic devices such as high-power transistors to be mounted in electric vehicles (EVs) and plug-in hybrid vehicles (PHVs).

As a method for producing Group III nitride crystals, an oxide vapor phase epitaxy (OVPE) method using Group III oxides as raw materials is used (see, for example, JP-2002-225075A).

Conventionally, in methods for producing Group III nitride crystals, as shown in FIG. 6, a wafer tray 50 housing a seed substrate 10 is made of transition metals such as stainless steel.

However, the inventors found that there was a problem in that, in the high-temperature environment for crystal growth, the backside of the GaN seed substrate 10 is significantly decomposed due to the catalytic action of the transition metal that constitutes the wafer tray 50. A seed substrate whose backside has been decomposed cannot be reused.

It was also found that there was a problem in that the transition metal constituting the wafer tray 50 itself reacted with Ga in the seed substrate 10 to form an alloy, causing changes in the shape and physical properties of the wafer tray 50. As a result, the wafer tray 50 could not be used repeatedly, that is, the wear cycle became faster.

### SUMMARY

The present disclosure is intended to solve the above-mentioned problems, and one non-limiting and exemplary embodiments provides a Group III nitride crystal production apparatus that includes a wafer tray on which a seed substrate is disposed and that is capable of suppressing reaction between the seed substrate and the wafer tray.

In one general aspect, the techniques disclosed here feature: a Group III nitride crystal production apparatus having a growth chamber in which a Group III element oxide gas reacts with a nitrogen-containing gas to grow a Group III nitride crystal on a seed substrate,

wherein the growth chamber includes a wafer tray on which the seed substrate is disposed via a decomposition-suppressing sheet.

In another general aspect, the techniques disclosed here feature: a wafer tray for use in producing a Group III nitride crystal,

the wafer tray being configured to dispose a seed substrate thereon via a decomposition-suppressing sheet disposed on the inside of an opening surface of the wafer tray on which the seed substrate is disposed.

The Group III nitride crystal production apparatus according to the present disclosure has a wafer tray on which the seed substrate is disposed via the decomposition-suppressing sheet, and hence is capable of suppressing reactions between the wafer tray and the seed substrate.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional view showing the cross-sectional configuration of a Group III nitride crystal production apparatus according to a first embodiment;

FIG. 2 is a schematic cross-sectional view showing the cross-sectional structure of a wafer tray used in the Group III nitride crystal production apparatus of FIG. 1;

FIG. 3 is a flowchart of a method for producing a Group III nitride crystal according to the first embodiment;

FIG. 4A is a schematic cross-sectional view showing the cross-sectional structure of a wafer tray used in a Group III nitride crystal production apparatus according to a second embodiment;

FIG. 4B is a schematic plan view showing the relationship between the projection of a first recess and the projection of a second recess as viewed from the front surface side of the wafer tray in FIG. 4A;

FIG. 5 is a plan view of a seed substrate disposed on the wafer tray of FIG. 4A, viewed from above; and

FIG. 6 is a schematic cross-sectional view showing the cross-sectional structure of a wafer tray on which a seed substrate is disposed in a conventional method for producing a Group III nitride crystal.

### DETAILED DESCRIPTION

Group III nitride crystal production apparatus according to a first aspect, has a growth chamber in which a Group III element oxide gas reacts with a nitrogen-containing gas to grow a Group III nitride crystal on a seed substrate,

wherein the growth chamber includes a wafer tray on which the seed substrate is disposed via a decomposition-suppressing sheet.

In the Group III nitride crystal production apparatus according to a second aspect in addition to the first aspect, the decomposition-suppressing sheet is disposed inside an opening surface of the wafer tray on which the seed substrate is disposed.

In the Group III nitride crystal production apparatus according to a third aspect in addition to the first or second aspect, the wafer tray has a two-tier structure including:

a first body having a first recess that houses the decomposition-suppressing sheet and;

a second body having a second recess that houses the seed substrate disposed via the decomposition-suppressing sheet, the second recess continuing from the first recess and connecting the first recess to the outside.

In the Group III nitride crystal production apparatus according to a fourth aspect in addition to the third aspect, the following relational expressions are satisfied:

x+y≤A+B and x≤A

where x: depth of the first recess of the wafer tray, y: depth of the second recess of the wafer tray, A: thickness of the decomposition-suppressing sheet, and B: thickness of the seed substrate.

In the Group III nitride crystal production apparatus according to a fifth aspect in addition to the third aspect, when viewed in the thickness direction of the wafer tray, the entire projection of the first recess lies inside the projection of the second recess.

In the Group III nitride crystal production apparatus according to a sixth aspect in addition to the third aspect, when viewed in the thickness direction of the wafer tray, a maximum diameter r of the projection of the first recess is smaller than a minimum diameter R of the seed substrate, satisfying a relational expression r<R.

In the Group III nitride crystal production apparatus according to a seventh aspect in addition to the third aspect, the first recess or the second recess has an inner wall surface tapered so that the inner diameter of the first recess or the second recess narrows from the bottom surface side toward the top surface side.

In the Group III nitride crystal production apparatus according to an eighth aspect in addition to any one of the first to seventh aspect, the decomposition-suppressing sheet is made of a material selected from the group consisting of SiC, alumina, BN, mullite, SiN, and zirconia.

A wafer tray for use in producing a Group III nitride crystal, according to ninth aspect, the wafer tray is configured to dispose a seed substrate thereon via a decomposition-suppressing sheet disposed on the inside of an opening surface of the wafer tray on which the seed substrate is disposed.

In the wafer tray according to tenth aspect, in addition to ninth aspect, the wafer tray has a two-tier structure including:

a first body having a first recess that houses the decomposition-suppressing sheet and;

a second body having a second recess that houses the seed substrate disposed via the decomposition-suppressing sheet, the second recess continuing from the first recess and connecting the first recess to the outside.

In the wafer tray according to eleventh aspect, in addition to tenth aspect, the following relational expressions are satisfied:

x+y≤A+B and x≤A

where x: depth of the first recess of the wafer tray, y: depth of the second recess of the wafer tray, A: thickness of the decomposition-suppressing sheet, and B: thickness of the seed substrate.

In the wafer tray according to twelfth aspect, in addition to tenth or eleventh aspect, when viewed in the thickness direction of the wafer tray, the entire projection of the first recess lies inside the projection of the second recess.

In the wafer tray according to thirteenth aspect, in addition to any one of tenth to twelfth aspects, when viewed in the thickness direction of the wafer tray, a maximum diameter r of the projection of the first recess is smaller than a minimum diameter R of the seed substrate, satisfying a relational expression r<R.

In the wafer tray according to fourteenth aspect, in addition to any one of tenth to twelfth aspects, the first recess or the second recess has an inner wall surface tapered so that the inner diameter of the first recess or the second recess narrows from the bottom surface side toward the top surface side.

Hereinafter, a Group III nitride crystal production apparatus and production method according to an embodiment, as well as a wafer tray for disposing a seed substrate thereon in the production apparatus and production method, will be described with reference to the drawings. Note that in the following description, like components are given like reference numerals, and description thereof will be omitted as appropriate.

### (First Embodiment)

### Overview of Group III Nitride Crystal Production Apparatus

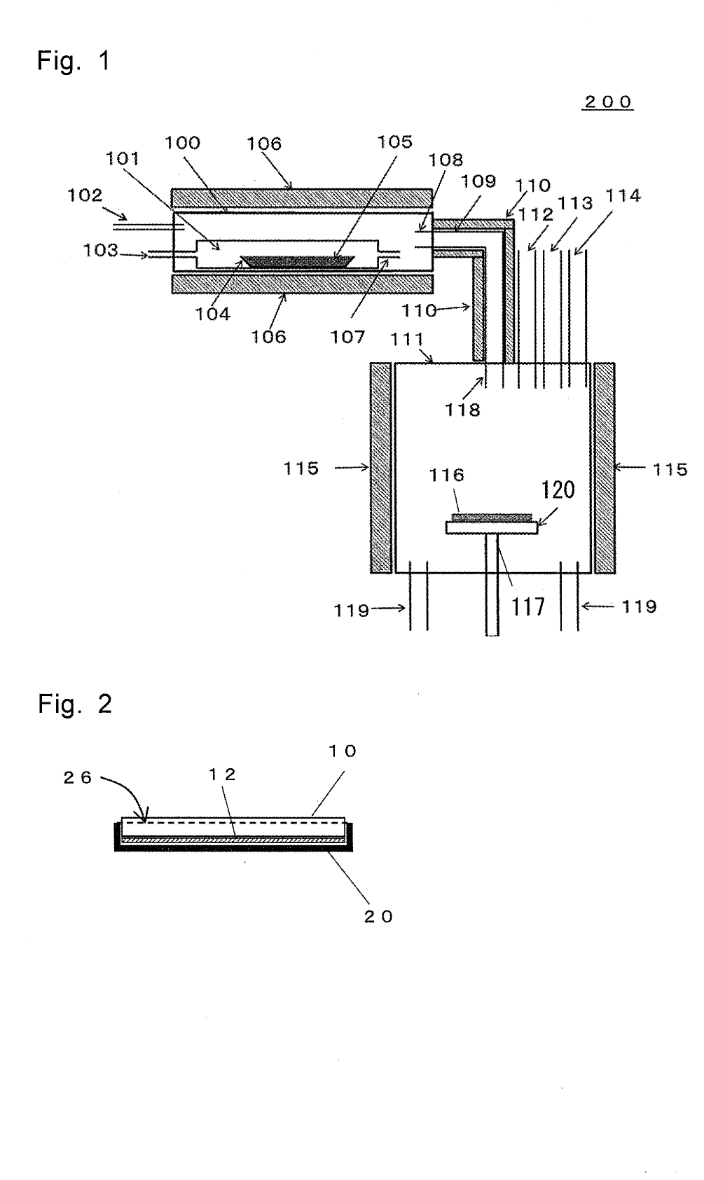

An overview of a Group III nitride crystal production apparatus 200 according to a first embodiment of the present disclosure will be described with reference to the schematic diagram of FIG. 1. FIG. 1 is a schematic cross-sectional view showing the cross-sectional configuration of the Group III nitride crystal production apparatus 200 according to the first embodiment. Note that FIG. 1 is a schematic view, and the sizes, proportions, etc. of the components may differ from the actual ones.

The Group III nitride crystal production apparatus 200 according to the first embodiment has a source chamber 100 for generating a Group III element oxide gas, and a growth chamber 111 for growing a Group III nitride crystal on a seed substrate 116.

A source reaction chamber 101 is disposed within the source chamber 100, and a source boat 104 carrying a starting Group III element source 105 is disposed within the source reaction chamber 101. In this embodiment, the starting Group III element source 105 is a starting Ga source. A reactive gas supply pipe 103 is connected to the source reaction chamber 101, supplying a reactive gas that reacts with the starting Group III element source 105. The source reaction chamber 101 has a Group III element oxide gas outlet 107. When the starting Group III element source 105 is an oxide, a reducing gas is used as the reactive gas. When the starting Group III element source 105 is a metal, an oxidizing gas is used as the reactive gas. The source chamber 100 is also provided with a first carrier gas inlet 102. The first carrier gas supplied from the first carrier gas inlet 102 carries the Group III element oxide gas discharged from the Group III element oxide gas outlet 107 through a gas outlet 108 and a connection pipe 109 to the growth chamber 111.

The growth chamber 111 has a gas inlet 118 for supplying a Group III element oxide gas and a first carrier gas, a third carrier gas inlet 112, a nitrogen-containing gas inlet 113, a second carrier gas inlet 114, and an exhaust port 119. A wafer tray 120 is disposed within the growth chamber 111 on which the seed substrate 116 is disposed via a decomposition-suppressing sheet. The wafer tray 120 is placed on a substrate susceptor 117, and the substrate susceptor 117 is placed on a rotation shaft 121. A fourth heater 122 is also disposed below the substrate susceptor 117.

### <Wafer Tray>

FIG. 2 is a schematic cross-sectional view showing the cross-sectional structure of a wafer tray 20 used in the Group III nitride crystal production apparatus of FIG. 1.

The wafer tray 20 has a body where the seed substrate 10 is disposed thereon via a decomposition-suppressing sheet 12. Because the seed substrate 10 is disposed via the decomposition-suppressing sheet 12, reaction between the wafer tray 20 and the seed substrate 10 may be suppressed. When the Group III nitride crystal is GaN, significant decomposition on the backside of the GaN of seed substrate 10 facing to the wafer tray 20 can be suppressed. Furthermore, because the transition metals constituting the wafer tray do not react with the Ga in the seed substrate, the lifetime of the wafer tray can be extended. Furthermore, because alloying between the Ga in the seed substrate and the transition metal in the wafer tray can be suppressed, adhesion between the backside of the seed substrate 10 and the front surface of the wafer tray can be suppressed. If adhesion occurs between the seed substrate and the wafer tray, the adhesion may cause cracking during cooling or when removing the grown crystal.

As shown in FIG. 2, the wafer tray 20 may have a body where the seed substrate 10 is disposed thereon via the decomposition-suppressing sheet 12. The decomposition-suppressing sheet 12 is disposed on the inside of an opening surface 26 on which the seed substrate 10 is disposed.

The wafer tray 20 is made of, for example, SiC, C (carbon), BN (boron nitride), transition metal, SiO₂ (quartz), SiN (silicon nitride), AlN (aluminum nitride), or the like.

Furthermore, the shape of the wafer tray 20 when viewed in the thickness direction (viewed from above) may be, for example, a circular shape, but is not limited to this and may be an elliptical shape, a polygonal shape, or a combination thereof.

### <Decomposition-Suppressing Sheet>

The decomposition-suppressing sheet 12 may be made of a material selected from the group consisting of, for example, SiC, alumina, BN, mullite, SiN, and zirconia. When the decomposition-suppressing sheet 12 made of one of these materials is used, it is possible to inhibit reaction of the Group III nitride crystal as the seed substrate 10 with the wafer tray, and the presence of the decomposition-suppressing sheet 12 makes it possible to suppress reaction between the seed substrate 10 and the wafer tray 20. The decomposition-suppressing sheet 12 may be also used for spacing between the seed substrate 10 and the wafer tray 20. Note that the decomposition-suppressing sheet 12 may be replaced as appropriate.

The maximum diameter of the decomposition-suppressing sheet 12 is equal to or smaller than the diameter of the wafer tray 20.

The above production apparatuses are merely examples and are not limited to these, and any apparatus may be used as long as it can use the above wafer trays.

### <Overview of Group III Nitride Crystal Production Method>

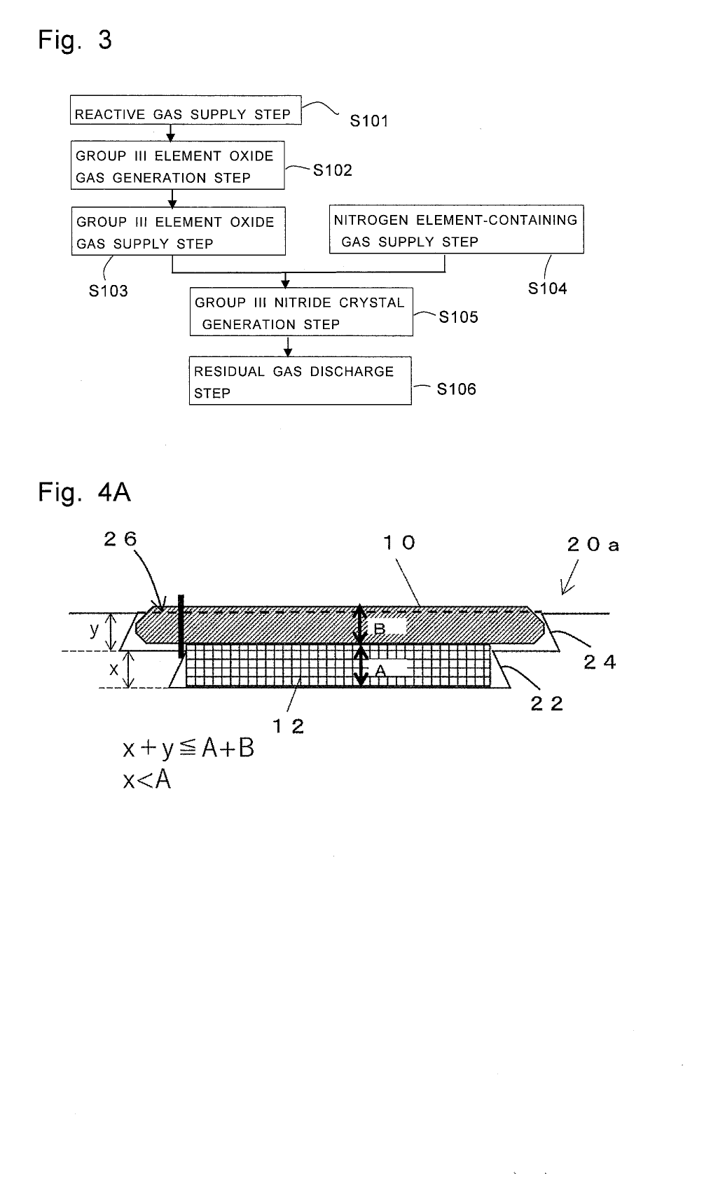

FIG. 3 is a flowchart of a method for manufacturing a Group III nitride crystal according to first embodiment. An overview of the method for manufacturing a Group III nitride crystal according to first embodiment of the present disclosure will be described with reference to the flowchart of FIG. 3. The method for manufacturing a Group III nitride crystal according to first embodiment includes a reactive gas supply step S101, a Group III element oxide gas generation step S102, a Group III element oxide gas supply step S103, a nitrogen-containing gas supply step S104, a Group III nitride crystal generation step S105, and a residual gas exhaust step S106.

In the reactive gas supply step S101, a reactive gas is supplied from the reactive gas supply pipe 103 to the source reaction chamber 101 in the source chamber 100. As described above, the reactive gas may be a reducing gas or an oxidizing gas, as necessary.

In the Group III element oxide gas generation step S102, the starting Group III element source 105 is reacted with a reactive gas (a reducing gas when the starting Group III element source is an oxide, and an oxidizing gas when the starting Group III element source is a metal) in the source reaction chamber 101 to generate a Group III element oxide gas.

In the Group III element oxide gas supply step S103, the Group III element oxide gas produced in the Group III element oxide gas generation step S102 is supplied to the growth chamber 111. The Group III element oxide gas is discharged from the source reaction chamber 101 through the Group III element oxide gas outlet 107, discharged from the gas outlet 108 together with the first carrier gas supplied from the first carrier gas inlet 102, transported through the connection pipe 109, and supplied into the growth chamber 111 from the gas inlet 118.

In the nitrogen-containing gas supply step S104, a nitrogen-containing gas is supplied from the nitrogen-containing gas inlet 113 to the growth chamber 111.

In the Group III nitride crystal generating step S105, the Group III element oxide gas supplied into the growth chamber 111 in the Group III element oxide gas supplying step S104 is reacted with the nitrogen-containing gas supplied into the growth chamber 111 in the nitrogen-containing gas supplying step, thereby growing a Group III nitride crystal on the seed substrate 116.

In the residual gas exhaust step S106, unreacted gases that do not contribute to the growth of the Group III nitride crystal are exhausted from the growth chamber 111 through the exhaust port 119.

In the flowchart, arrows indicate the connections between steps, but in reality, the steps shown in the flowchart may be performed simultaneously. In the flowchart, arrows indicate connections from steps performed upstream in the Group III nitride crystal production apparatus to steps performed downstream.

### <Details of Method and Apparatus for Producing Group III Nitride Crystal>

The following describes in detail the method for producing a Group III nitride crystal according to the present first embodiment. In the present first embodiment, metallic Ga is used as the starting Group III element source 105.

In the reactive gas supply step S101, a reactive gas is supplied from the reactive gas supply pipe 103 to the source reaction chamber 101. In the example of the first embodiment, metal Ga is used as the Group III element source 105, and therefore H₂O gas is used as the reactive gas. Note that O₂ gas, CO gas, NO gas, N₂O gas, NO₂ gas, and N₂O₄gas mayalso be used as the reactive gas.

In the Group III element oxide gas generation step S102, the reactive gas supplied to the source reaction chamber 101 in the reactive gas supply step S101 reacts with Ga, which is the starting Group III element source 105, to generate Ga₂O gas, which is a Group III element oxide gas. The generated Ga₂O gas is discharged from the source reaction chamber 101 to the source chamber 100 via the Group III element oxide gas outlet 107. The discharged Ga₂O gas is mixed with afirst carriergas suppliedfrom the first carrier gas inlet 102 to the source chamber 100, and the mixture is supplied to the gas outlet 108.

In the first embodiment, the source chamber 100 is heated by a first heater 106. When the source chamber 100 is heated, the temperature of the source chamber 100 is preferably set to 800 °C or higher, which is higher than the boiling point of Ga₂O gas. The temperature of the source chamber 100 is preferably set to a lower temperature than that of the growth chamber 111. As will be described later, when the growth chamber 111 is heated by a second heater 115, the temperature of the source chamber 100 is preferably set to, for example, less than 1800 °C. The starting Group III element source 105 is placed in a source boat 104 disposed in the source reaction chamber 101. The source boat 104 preferably has a shape that can increase the contact area between the reactive gas and the starting Group III element source 105. For example, the source boat 104 preferably has a multi-tiered dish shape to prevent the starting Group III element source 105 and the reactive gas from passing through the source reaction chamber 101 without contacting each other.

Methods for generating a Group III element oxide gas can be broadly classified into methods for reducing the starting Group III element source 105 and methods for oxidizing the starting Group III element source 105. For example, the reduction method uses an oxide (e.g., Ga₂O₃) as the starting Group III element source 105and a reducing gas (e.g., H₂ gas, CO gas, CH₄ gas, C₂H₆ gas, H₂S gas, or SO₂ gas) as ₜhe reactive gas.

On the other hand, in the oxidation method, the material to be oxidized (e.g., liquid Ga) is used as the starting Group III element source 105, and an oxidizing gas (e.g., H₂O gas, O₂ gas, CO gas, NO gas, N₂O gas, NO₂ gas, or N₂O₄ gas) is used as the reactive gas. In additionto aGa source, anIn source or an Al source may also be used as the starting Group III element source 105. An inert gas, H₂ gas, or the like may be used as the first carrier gas.

In the Group III element oxide gas supply step S103, Ga₂O gas generated in the Group III element oxide gas generation step S102 is supplied to the growth chamber 111 via the gas outlet 108, the connection pipe 109, and the gas inlet 118. If the temperature of the connection pipe 109 connecting the source chamber 100 and the growth chamber 111 drops below the temperature of the source chamber 100, a reverse reaction of the reaction for generating the Group III element oxide gas may occur, and the starting Group III element source 105 may precipitate inside the connection pipe 109. Therefore, it is preferable that the connection pipe 109 be heated by a third heater 110 so that the temperature does not drop below the temperature of the source chamber 100.

In the nitrogen-containing gas supply step S104, a nitrogen-containing gas is supplied from the nitrogen-containing gas inlet 113 to the growth chamber 111. Examples of the nitrogen-containing gas include NH₃ gas,_{,} NOgas,_{,} NO₂gas,N₂O gas, N₂O₄ gas, N₂H₂gas, and N₂H₄gas.

In the Group III nitride crystal growth step S105, the source gases supplied into the growth chamber 111 after each supply step are reacted to grow a Group III nitride crystal on the seed substrate 116. The growth chamber 111 is preferably heated by the second heater 115 to a temperature at which the Group III element oxide gas and the nitrogen-containing gas react. At this time, in order to prevent a reverse reaction of the reaction that produces the Group III element oxide gas, it is preferable to control the temperature of the growth chamber 111 so that it does not fall below the temperatures of the source chamber 100 and the connection pipe 109. The temperature of the growth chamber 111 heated by the second heater 115 is preferably 1000 °C or higher and 1800 °C or lower.

By mixing the Group III element oxide gas supplied to the growth chamber 111 via the Group III element oxide gas supply step S103 and the nitrogen-containing gas supplied to the growth chamber 111 via the nitrogen-containing gas supply step S104 upstream of the seed substrate 116, it is possible to grow a Group III nitride crystal on the seed substrate 116.

It should be noted that the above-described manufacturing method is merely an example, and the Group III nitride crystal production apparatus according to the first embodiment is not limited to the above-described manufacturing method, but can implement any method for manufacturing Group III nitride crystals that can use the wafer trays.

### (Second Embodiment)

### <Wafer Tray>

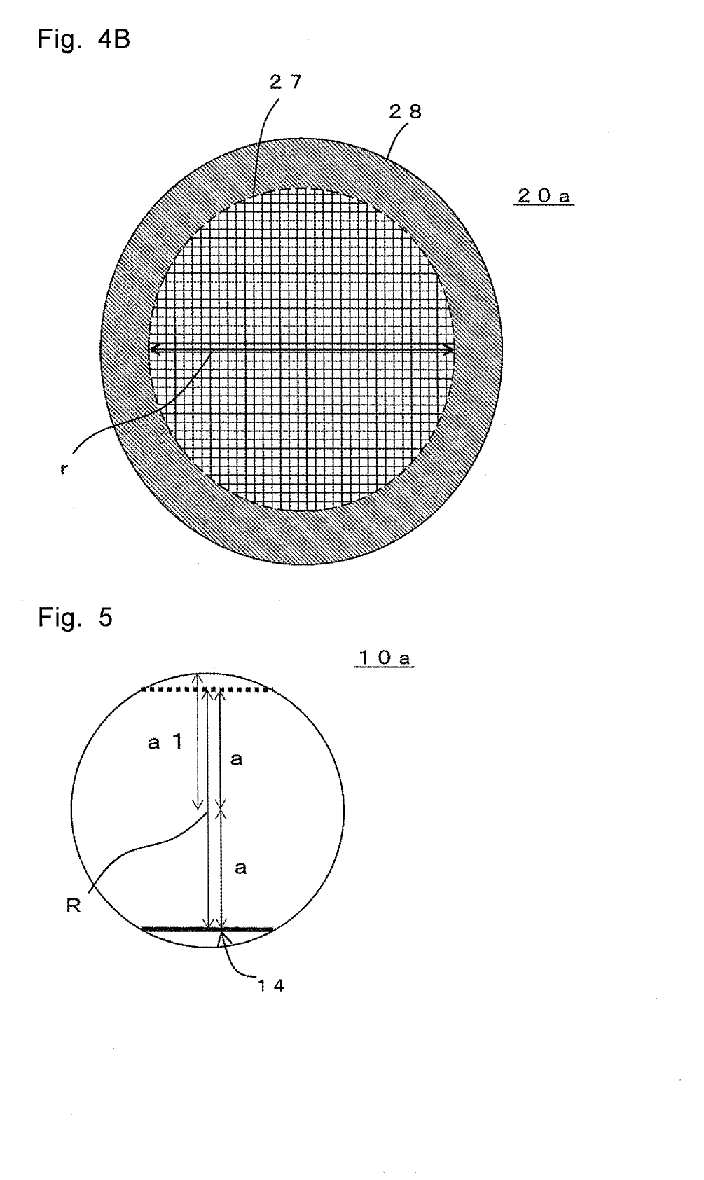

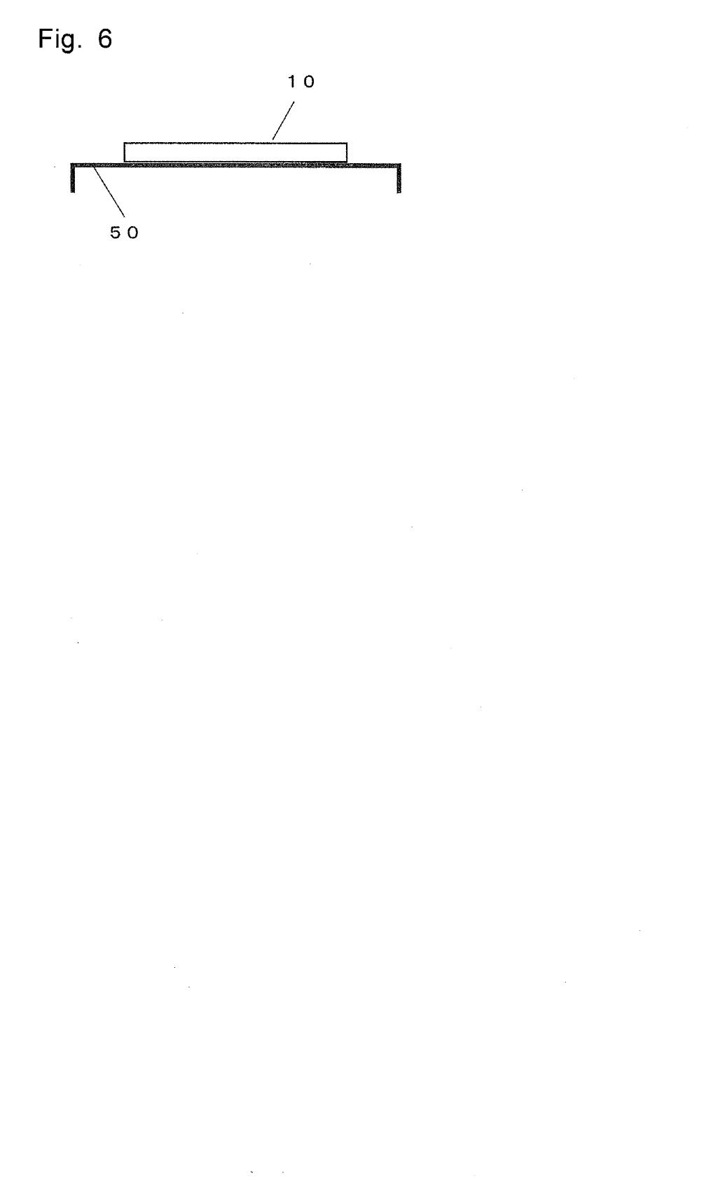

FIG. 4A is a schematic cross-sectional view showing the cross-sectional structure of a wafer tray 20a according to second embodiment. FIG. 4B is a schematic plan view showing the relationship between a projection 27 of a first recess 22 and a projection 28 of a second recess 24 as viewed from the front surface side of the wafer tray 20a in FIG. 4A. FIG. 5 is a plan view showing a seed substrate 10a disposed on the wafer tray 20a in FIG. 4A as viewed from above.

As shown in FIG. 4A, the wafer tray 20a houses the seed substrate 10 thereon via the decomposition-suppressing sheet 12 disposed on the inside of the opening surface 26 on which the seed substrate 10 is disposed.

Furthermore, the wafer tray 20a has a two-tier structure including a first body having the first recess 22 that houses the decomposition-suppressing sheet 12, and a second body having the second recess 24 that houses the seed substrate 10 disposed via the decomposition-suppressing sheet 12, continues from the first recess 22, and connects the first recess 22 to the outside. The wafer tray 20a has a two-tier structure, so that the decomposition-suppressing sheet 12 may be held more stably, and further the seed substrate 10 may be disposed on top of the decomposition-suppressing sheet 12, thereby suppressing direct contact between the wafer tray 20a and the seed substrate 10.

Furthermore, the wafer tray 20a may satisfy the relational expressions x+y≤A+B and x≤A with respect to following parameters among the depth x of the first recess 22 of the wafer tray 20a, the depth y of the second recess 24, the thickness A of the decomposition-suppressing sheet 12, and the thickness B of the seed substrate 10. When the thickness A of the decomposition-suppressing sheet 12 is larger than the depth x of the first recess 22 (x≤A), the back surface of the seed substrate 10 can be held so as not to come into contact with the step between the first recess 22 and the second recess 24 of the wafer tray 20a when the seed substrate 10 is disposed on the decomposition-suppressing sheet 12. Furthermore, the sum (A+B) of the thickness A of the decomposition-suppressing sheet 12 and the thickness B of the seed substrate 10 may be equal to or larger than the sum (x+y) of the depth x of the first recess 22 and the depth y of the second recess 24. This allows the surface of the seed substrate 10 to protrude outward from the opening surface 26 defined by the periphery of the wafer tray 20a.

Furthermore, as shown in FIG. 4B, the entire projection 27 of the first recess 22 as viewed in the thickness direction of the wafer tray 20a may be located inside the projection 28 of the second recess 24. This suppresses exposure of the decomposition-suppressing sheet 12 accommodated in the first recess 22 from the seed substrate 10.

In FIG. 4B, the projection 27 of the first recess 22 and the projection 28 of the second recess 24 when viewed in the thickness direction (viewed from above) are both circular, but this is not limited to this and may be an elliptical shape, a polygonal shape, or a combination thereof.

Furthermore, the maximum diameter r (FIG. 4B) of the projection of the first recess 22 as viewed in the thickness direction (viewed from above) of the wafer tray 20a may satisfy the relational expression r<R, that is, smaller than the minimum diameter R (FIG. 5) of the seed substrate. The seed substrate 10a in FIG. 5 has an orientation flat 14. In this case, the minimum diameter R is not twice the radius a1, but is, for example, twice the length a from the wafer center to the orientation flat 14, i.e., 2a. Even in such a case, as long as the relational expression r<R is satisfied, drop of the seed substrate 10a into the first recess 22 can be suppressed. Furthermore, exposure of the decomposition-suppressing sheet 12 accommodated in the first recess 22 can be suppressed. Note that the maximum diameter of the decomposition-suppressing sheet 12 is equal to or smaller than the maximum diameter r of the first recess 22. This suppresses exposure of a portion of the decomposition-suppressing sheet from below the seed substrate 10a, even when the seed substrate 10a having the orientation flat 14 rotates about the wafer center. This can suppress exposure of a portion of the decomposition-suppressing sheet from being exposed and precipitation of polycrystalline GaN on the exposed decomposition-suppressing sheet.

Furthermore, the first recess (first body) 22 and /or the second recess (second body) 24 may have a tapered inner wall surface so that the inner diameter of the first recess 22 and/or the second recess 24 narrows from the bottom side toward the top side. This suppresses jumping-out of the decomposition-suppressing sheet 12 and/or the seed substrate 10 from the wafer tray in rotation.

### REFERENCE SIGNS LIST

10 seed substrate

12 decomposition-suppressing sheet

14 orientation flat

20, 20a wafer tray

22 first recess (first body)

24 second recess (second body)

26 opening surface

27 projection of first recess

28 projection of second recess

50 wafer tray

100 source chamber

101 source reaction chamber

102 first carrier gas inlet

103 reactive gas supply pipe

104 source boat

105 starting Group III element source

106 first heater

107 Group III element oxide gas outlet

108 gas outlet

109 connection pipe

110 third heater

111 growth chamber

112 third carrier gas inlet

113 nitrogen-containing gas inlet

114 second carrier gas inlet

115 second heater

116 seed substrate

117 substrate susceptor

118 gas inlet

119 exhaust port

120 wafer tray

121 rotation axis

122 fourth heater

200 Group III nitride crystal production apparatus

r maximum projection diameter of first recess

R minimum diameter of seed substrate

What is claimed is:

1. A Group III nitride crystal production apparatus having a growth chamber in which a Group III element oxide gas reacts with a nitrogen-containing gas to grow a Group III nitride crystal on a seed substrate,
wherein the growth chamber includes a wafer tray on which the seed substrate is disposed via a decomposition-suppressing sheet.

2. The Group III nitride crystal production apparatus according to claim 1,
wherein the decomposition-suppressing sheet is disposed inside an opening surface of the wafer tray on which the seed substrate is disposed.

3. The Group III nitride crystal production apparatus according to claim 1,
wherein the wafer tray has a two-tier structure including:
a first body having a first recess that houses the decomposition-suppressing sheet and;
a second body having a second recess that houses the seed substrate disposed via the decomposition-suppressing sheet, the second recess continuing from the first recess and connecting the first recess to the outside.

4. The Group III nitride crystal production apparatus according to claim 3,
wherein the following relational expressions are satisfied:
x+y≤A+B and x≤A
where x: depth of the first recess of the wafer tray, y: depth of the second recess of the wafer tray, A: thickness of the decomposition-suppressing sheet, and B: thickness of the seed substrate.

5. The Group III nitride crystal production apparatus according to claim 3,
wherein when viewed in the thickness direction of the wafer tray, the entire projection of the first recess lies inside the projection of the second recess.

6. The Group III nitride crystal production apparatus according to claim 3,
wherein when viewed in the thickness direction of the wafer tray, a maximum diameter r of the projection of the first recess is smaller than a minimum diameter R of the seed substrate, satisfying a relational expression r<R.

7. The Group III nitride crystal production apparatus according to claim 3,
wherein the first recess or the second recess has an inner wall surface tapered so that the inner diameter of the first recess or the second recess narrows from the bottom surface side toward the top surface side.

8. The Group III nitride crystal production apparatus according to claim 1,
wherein the decomposition-suppressing sheet is made of a material selected from the group consisting of SiC, alumina, BN, mullite, SiN, and zirconia.

9. A wafer tray for use in producing a Group III nitride crystal,
the wafer tray being configured to house a seed substrate thereon via a decomposition-suppressing sheet disposed on the inside of an opening surface of the wafer tray on which the seed substrate is disposed.

10. The wafer tray according to claim 9,
wherein the wafer tray has a two-tier structure including:
a first body having a first recess that houses the decomposition-suppressing sheet and;
a second body having a second recess that houses the seed substrate disposed via the decomposition-suppressing sheet, the second recess continuing from the first recess and connecting the first recess to the outside.

11. The wafer tray according to claim 10,
wherein the following relational expressions are satisfied:
x+y≤A+B and x≤A
where x: depth of the first recess of the wafer tray, y: depth of the second recess of the wafer tray, A: thickness of the decomposition-suppressing sheet, and B: thickness of the seed substrate.

12. The wafer tray according to claim 10,
wherein when viewed in the thickness direction of the wafer tray, the entire projection of the first recess lies inside the projection of the second recess.

13. The wafer tray according to claim 10,
wherein when viewed in the thickness direction of the wafer tray, a maximum diameter r of the projection of the first recess is smaller than a minimum diameter R of the seed substrate, satisfying a relational expression r<R.

14. The wafer tray according to claim 10,
wherein the first recess or the second recess has an inner wall surface tapered so that the inner diameter of the first recess or the second recess narrows from the bottom surface side toward the top surface side.

15. The wafer tray according to claim 9,
wherein the decomposition-suppressing sheet is made of a material selected from the group consisting of SiC, alumina, BN, mullite, SiN, and zirconia.
